(19) United States
(12) Patent Application Publication
(10) Pub. No.: US 2026/0287679 A1
(43) Pub. Date: Sep. 24, 2026

(54) MODULAR CABLE

(71) Applicants: CHANNEL WELL TECHNOLOGY CO., LTD., Taoyuan City (TW); CYBENETICS LTD, Nicosia (CY); CHIA KWEI TECHNOLOGY (GUANG ZHOU)CO., LTD, GuangZhou (CN); CHANNEL WELL TECHNOLOGY (GUANGZHOU) CO., LTD., GuangZhou (CN); POWER PLUS TECHNOLOGY (WANZAI) CORP, Yichun City (CN); Ningbo Iso Electronic Co., Ltd, NINGBO (CN); Young Ling Enterprise Company Limited, Apia (WS); POWER PLUS TECHNOLOGY (VIETNAM) CORP, Que Vo Communc (VN); CHANNEL WELL TECHNOLOGY (VIETNAM) CO., LTD., Hanoi City (VN)

(72) Inventors: YEN-CHENG PAN, Taoyuan City (TW); CHIH-CHIANG HUANG, Taoyuan City (TW); Aristeidis Bitziopoulos, Nicosia (CY)

(73) Assignees: CHANNEL WELL TECHNOLOGY CO., LTD., Taoyuan City (TW); CYBENETICS LTD, Nicosia (CY); CHIA KWEI TECHNOLOGY (GUANG ZHOU)CO., LTD, GuangZhou (CN); CHANNEL WELL TECHNOLOGY (GUANGZHOU) CO., LTD., GuangZhou (CN); POWER PLUS TECHNOLOGY (WANZAI) CORP, Yichun City (CN); Ningbo Iso Electronic Co., Ltd, NINGBO (CN); Young Ling Enterprise Company Limited, Apia (WS); POWER PLUS TECHNOLOGY (VIETNAM) CORP, Que Vo Communc (VN); CHANNEL WELL TECHNOLOGY (VIETNAM) CO., LTD., Hanoi City (VN)

(21) Appl. No.: 19/339,365

(22) Filed: Sep. 25, 2025

(30) Foreign Application Priority Data
Mar. 18, 2025 (TW) 114110148

(51) Int. Cl. G01R 31/58; G01K 3/08; G01R 19/165; H01H 83/10; H01H 83/20

(52) U.S. Cl. CPC G01R 31/58; G01K 3/08; G01R 19/16571; G01R 19/16576; H01H 83/10; H01H 83/20

(57) ABSTRACT

A modular cable connect an electronic device with a power supply unit and has the function of protecting the electronic device, including: a plurality of cables; a first connector electrically connected to one end of the plurality of cables, the first connector being configured to detachably connect to the electronic device; a second connector electrically connected to the other end of the plurality of cables, the second connector being configured to detachably connect to the power supply unit; and a detection device is disposed on the plurality of cables, between the first connector and the second connector, the detection device is configured to detect a working status all of the plurality of cables, and when the working status is abnormal, disconnect specific of the electrical paths in the plurality of cables between the first connector and the second connector, so that the electronic device stops working.

### CROSS-REFERENCE TO RELATED APPLICATION

This non-provisional application claims priority under 35 U.S.C. § 119(a) on Patent Application No(s). 114110148 filed in Taiwan, R.O.C. on Mar. 18, 2025, the entire contents of which are hereby incorporated by reference.

### BACKGROUND OF THE INVENTION

### 1. Field of the Invention

The present disclosure relates to cables, and in particular, to a modular cable having a function of protecting an electronic device.

### 2. Description of the Related Art

With the improvement of processing efficiency of a computer system, power consumption of electronic devices (such as a processor and a display card) in the computer system is also increasing. For example, the power consumption of the display card may reach 450 W to 600 W, or even higher wattage. The foregoing display card usually needs an additional power supply unit, and the power supply unit provides working power to the display card for use through a cable.

### BRIEF SUMMARY OF THE INVENTION

However, in recent experience of using a display card, a situation where a connector of the display card and a connector of a power supply unit are melted simultaneously occurs. The reason for the melting may be that some cables are in poor contact between the power supply unit and the display card, or a cable is bent, causing a current to be concentrated on some lines, and a temperature of the cable to rise, which leads to melting. In severe cases, the display card may even be burned. Therefore, the current cables lack a function of protecting an electronic device based on a working status thereof.

To solve the foregoing problem, the present disclosure is intended to provide a modular cable, connected to an electronic device and a power supply unit, having a function of protecting the electronic device, and including: a plurality of cables; a first connector, electrically connected to one ends of the plurality of cables, the first connector being configured to detachably connect to the electronic device; a second connector, electrically connected to other ends of the plurality of cables, the second connector being configured to detachably connect to the power supply unit; and a monitoring device, arranged on the plurality of cables and located between the first connector and the second connector, the monitoring device being configured to monitor a working status of all electrical paths of the plurality of cables, and when the working status is abnormal, open a specific electrical path in the plurality of cables between the first connector and the second connector, so that the electronic device stops working.

In some embodiments, the first connector and the second connector are 12VHPWR connectors, and the specific electrical path refers to a path electrically connected to a pin of the 12VHPWR connector that is defined as S0.

In some embodiments, the first connector and the second connector are 12VHPWR connectors, and the specific electrical path refers to a path electrically connected to a pin of the 12VHPWR connector that is defined as S1.

In some embodiments, the monitoring device is further provided with a temperature monitoring circuit, which is configured to monitor a working temperature of at least one electrical path in the plurality of cables, and when the working temperature of the at least one electrical path is greater than a preset temperature value, confirm that the working status is abnormal, and open the specific electrical path.

In some embodiments, the monitoring device is further provided with a current monitoring circuit, which is configured to monitor a working current of at least one electrical path in the plurality of cables, and when the working current of the at least one electrical path is greater than a preset current value, confirm that the working status is abnormal, and open the specific electrical path.

In some embodiments, the monitoring device is further provided with a voltage monitoring circuit, which is configured to monitor a working voltage of at least one electrical path in the plurality of cables, and when the working voltage of the at least one electrical path is less than a preset voltage value, confirm that the working status is abnormal, and open the specific electrical path.

In some embodiments, the monitoring device is arranged in a cable organizer. The cable organizer includes: a first clamp, configured to cover upper surfaces of a set of cables of the plurality of cables; a second clamp, configured to be engaged with the first clamp to fix the cable organizer to the plurality of cables; and a base body, arranged between the first clamp and the second clamp, and configured to accommodate and arrange the plurality of cables.

In some embodiments, the monitoring device further includes a printed circuit board arranged between the second clamp and the base body.

In some embodiments, the printed circuit board is further provided with a plurality of piercing terminals, which are configured to pierce insulating outer sheaths of the plurality of cables and electrically connect to core wires in the plurality of cables, to obtain the working status of the plurality of cables.

In some embodiments, the monitoring device is a temperature control switch, which is configured to monitor a working temperature of at least one electrical path in the plurality of cables, and when the working temperature of the at least one electrical path is greater than a preset temperature value, confirm that the working status is abnormal, and open the specific electrical path.

In some embodiments, the monitoring device is close to the first connector, the first connector has a first arrangement direction, the second connector has a second arrangement direction, and an included angle between the first arrangement direction and the second arrangement direction is 90 degrees.

Based on the above, through the modular cable of the present disclosure, it may be determined, by monitoring the working status (for example, a working temperature, a working current, and/or a working voltage) of the plurality of cables, whether the cable may be abnormal, and when it is confirmed that the working status is abnormal, and a specific electrical path in the plurality of cables between the first connector and the second connector is opened, so that the electronic device stops working, thereby achieving the function of instantly protecting the electronic device. In addition, although the electronic device stops working due to the protection function, the power supply unit for supplying power to the electronic device can still operate normally. Therefore, the computer system is not shut down just because the electronic device stops working, and some operating functions of the computer system may still be maintained, thereby improving use reliability of the computer system.

### BRIEF DESCRIPTION OF THE DRAWINGS

FIG. 1 is a schematic diagram showing a modular cable arranged between an electronic device and a power supply unit according to an embodiment of the present disclosure.

FIG. 2 is a partial schematic diagram showing an appearance of a monitoring device arranged in a cable organizer according to an embodiment of the present disclosure.

FIG. 3 is a schematic diagram showing an exploded structure of a cable organizer according to an embodiment of the present disclosure.

FIG. 4 is a partial schematic structural diagram showing a plurality of cables arranged on a printed circuit board according to an embodiment of the present disclosure.

FIG. 5 is a partial schematic structural diagram showing a plurality of cables arranged on a printed circuit board according to another embodiment of the present disclosure.

FIG. 6A is a partial schematic diagram showing an appearance of a monitoring device arranged in a plurality of cables according to still another embodiment of the present disclosure.

FIG. 6B is a partial schematic diagram showing an appearance of a monitoring device arranged in a plurality of cables after being flipped 180 degrees according to FIG. 6A.

FIG. 7 is a schematic structural diagram showing an appearance according to still another embodiment of the present disclosure.

FIG. 8 is a schematic structural diagram showing an appearance according to yet another embodiment of the present disclosure.

### DETAILED DESCRIPTION OF THE INVENTION

Specific structure or function descriptions in embodiments of the present disclosure described in this specification are provided only as examples for describing embodiments according to the concept of the present disclosure. The embodiments according to the concept of the present disclosure may be practiced in various forms, and should not be construed as a limitation on the embodiments described in the specification.

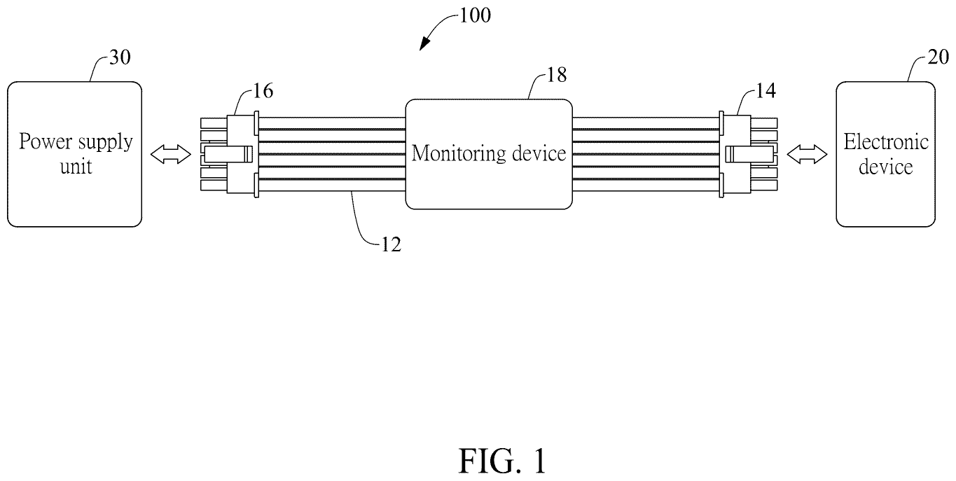

FIG. 1 is a schematic diagram showing a modular cable 100 arranged between an electronic device 20 and a power supply unit 30 according to an embodiment of the present disclosure.

Referring to FIG. 1, the modular cable 100 may be configured to connect the electronic device 20 to the power supply unit 30. The electronic device 20 may be a display card or another electronic device, for example, a motherboard, an optical disk drive, a solid-state hard disk, or a redundant array of independent disks (RAID) device. In the embodiments of the present disclosure, an example in which the electronic device 20 is a display card is used for description below.

The modular cable 100 may include a plurality of cables 12, a first connector 14, a second connector 16, and a monitoring device 18.

The plurality of cables 12 are configured to connect the first connector 14 and the second connector 16. The plurality of cables 12 are used as a plurality of electrical paths between the first connector 14 and the second connector 16. Each of the plurality of cables 12 may be composed of an insulating outer sheath and a core wire. In this embodiment, a quantity of the plurality of cables 12 is 16, but the present disclosure is not limited thereto, and a quantity of the plurality of cables 12 may be more than 16 or less than 16.

The first connector 14 is electrically connected to one ends of the plurality of cables 12. The first connector 14 is configured to detachably connect to the electronic device 20. The first connector 14 may be for example composed of a 12VHPWR connector.

The second connector 16 is electrically connected to other ends of the plurality of cables 12. The second connector 16 is configured to detachably connect to the power supply unit 30. The second connector 16 may be for example composed of a 12VHPWR connector. In another embodiment, the second connector 16 may also be for example composed of two dual 8-pin connectors.

It should be particularly noted that the modular cable 100 in the embodiments of the present disclosure adopts a modular design, and may be electrically connected to or opened from the electronic device 20 and the power supply unit 30 quickly through the structure of the first connector 14 and the second connector 16.

The monitoring device 18 has a printed circuit board 181. The monitoring device 18 may be arranged on the plurality of cables 12. The monitoring device 18 may be located between the first connector 14 and the second connector 16. The monitoring device 18 may be configured to monitor a working status of the plurality of cables 12, and when the working status is abnormal, open a specific electrical path in the plurality of cables 12 between the first connector 14 and the second connector 16, so that the electronic device 20 stops working.

For example, the current display card of the PCIe 5.0 standard needs to be equipped with a 16-pin power supply connector (that is, a 12VHPWR connector), to provide maximum power supply wattage of 600 W.

Pin assignment of the foregoing 12VHPWR connector is shown in Table 1 below.

TABLE 1
Pin assignment of the 12VHPWR connector

| Pin position | Signal | Color |
|---|---|---|
| 1 | +12 V3/V4 | Yellow |
| 2 | +12 V3/V4 | Yellow |
| 3 | +12 V3/V4 | Yellow |
| 4 | +12 V3/V4 | Yellow |
| 5 | +12 V3/V4 | Yellow |
| 6 | +12 V3/V4 | Yellow |
| S1 | CARD_PWR_STABLE | Blue |
| S2 | CARD_CBL_PRES# | Blue |
| 7 | COM | Black |
| 8 | COM | Black |
| 9 | COM | Black |
| 10 | COM | Black |
| 11 | COM | Black |
| 12 | COM | Black |
| S3 | SENSE0 | Blue |
| S4 | SENSE1 | Blue |

When the pin S0 and the pin S1 of the 12VHPWR connector are grounded, the power supply unit 30 may provide the electronic device 20 with the maximum power supply wattage of 600 W through the modular cable 100. In another embodiment, the power supply unit 30 may also provide the electronic device 20 with power supply wattage higher than 600 W through the modular cable 100.

In this embodiment, two specific electrical paths in the plurality of cables 12 between the first connector 14 and the second connector 16 are opened, so that the electronic device 20 stops working. When the monitoring device 18 monitors that the working status of the plurality of cables 12 is abnormal, the path defined as S0 in the plurality of cables 12 between the first connector 14 and the second connector 16 may be opened, or the path defined as S1 in the plurality of cables 12 between the first connector 14 and the second connector 16 may be opened, or the paths defined as S0 and S1 in the plurality of cables 12 between the first connector 14 and the second connector 16 may be opened, so that the electronic device 20 stops working to achieve the function of protecting the electronic device 20. In addition, in another embodiment, three or more specific electrical paths in the plurality of cables 12 between the first connector 14 and the second connector 16 may also be opened, so that the electronic device 20 stops working.

The operating principle of the foregoing function of protecting the electronic device 20 is based on the specification of the PCIe 5.0 standard. When a pin of the 12VHPWR connector is defined as S0 or S1 that is open, the electronic device 20 stops working and presents a screen-off state, which indicates that the power supply unit 30 still supplies power, but the electronic device 20 does not work or consume power, so as to avoid a problem that the plurality of cables 12 may be burned due to a high temperature caused by an excessively large working current or an excessively small working voltage, thereby achieving the function of protecting the electronic device 20.

It should be particularly noted that when the monitoring device 18 monitors that the working status of the plurality of cables 12 is abnormal, although the electronic device 20 is to stop working, the power supply unit 30 may still work normally and provide power to another device for use. In this way, the computer system is not shut down just because the electronic device 20 stops working, and some operating functions of the computer system may still be maintained, thereby improving use reliability of the computer system.

A monitoring manner and an operation manner of the monitoring device 18 are to be described by way of examples below.

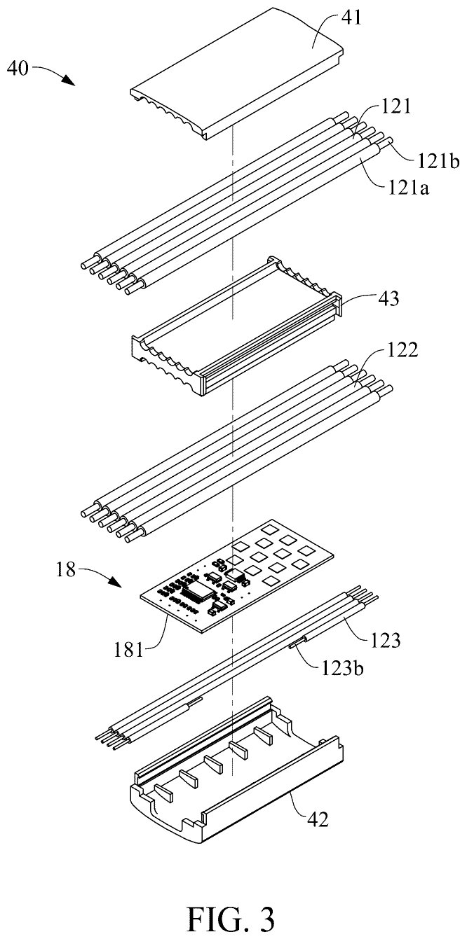

In some embodiments, the monitoring device 18 may include a printed circuit board 181 (as shown in FIG. 3). The printed circuit board 181 in the monitoring device 18 may be provided with a temperature monitoring circuit. The temperature monitoring circuit may be for example composed of circuit elements such as a plurality of thermistors, a buzzer, and a microcontroller. Each thermistor may correspondingly sense a temperature of each cable. The temperature monitoring circuit may be configured to monitor a working temperature of at least one electrical path in the plurality of cables 12. When the working temperature of the at least one electrical path is greater than a preset temperature value, the microcontroller confirms that the working status of the plurality of cables 12 is abnormal, and cuts off a specific electrical path (for example, a pin S0 or a pin S1) in the plurality of cables 12 between the first connector 14 and the second connector 16, so that the electronic device 20 stops working. The preset temperature value may be determined by obtaining, through experiments, a temperature value at which the plurality of cables 12 may be burned due to a high temperature. In addition, in another embodiment, when a working temperature of at least one electrical path is greater than a preset temperature value, the microcontroller confirms that the working status of the plurality of cables 12 is abnormal, and the microcontroller may cause the buzzer operate to generate a sound to remind a user that the working status of the plurality of cables 12 is abnormal.

In some embodiments, the printed circuit board 181 in the monitoring device 18 may be provided with a current monitoring circuit. The current monitoring circuit may be for example composed of circuit elements such as a plurality of resistors, a plurality of comparators, a buzzer, and a microcontroller. The current monitoring circuit may be configured to monitor a working current of at least one electrical path in the plurality of cables 12. When the working current of the at least one electrical path is greater than a preset current value, the microcontroller confirms that the working status of the plurality of cables 12 is abnormal, and opens a specific electrical path (for example, a pin S0 or a pin S1) in the plurality of cables 12 between the first connector 14 and the second connector 16, so that the electronic device 20 stops working. The preset current value may be determined by obtaining, through experiments, a current value at which the plurality of cables 12 may be burned due to a high temperature. In another embodiment, when a working current of at least one electrical path is greater than a preset current value, the microcontroller confirms that the working status of the plurality of cables 12 is abnormal, and the microcontroller may cause the buzzer operate to generate a sound to remind a user that the working status of the plurality of cables 12 is abnormal.

In some embodiments, the printed circuit board 181 in the monitoring device 18 may be provided with a voltage monitoring circuit. The voltage monitoring circuit may be for example composed of a plurality of resistors and a microcontroller. The voltage monitoring circuit may be configured to monitor a working voltage of at least one electrical path in the plurality of cables 12. When the working voltage of the at least one electrical path is less than a preset voltage value, the microcontroller confirms that the working status of the plurality of cables 12 is abnormal, and opens a specific electrical path (for example, a pin S0 or a pin S1) in the plurality of cables 12 between the first connector 14 and the second connector 16, so that the electronic device 20 stops working. The preset voltage value may be determined by obtaining, through experiments, a voltage value at which the plurality of cables 12 may be burned due to a high temperature. In another embodiment, when a working voltage of at least one electrical path is less than a preset voltage value, the microcontroller confirms that the working status of the plurality of cables 12 is abnormal, and the microcontroller may cause the buzzer operate to generate a sound to remind a user that the working status of the plurality of cables 12 is abnormal.

In some embodiments, the printed circuit board 181 in the monitoring device 18 may be provided with a temperature and current monitoring circuit. The temperature and current monitoring circuit may be for example composed of circuit elements such as a plurality of thermistors, a plurality of resistors, a plurality of comparators, and a microcontroller. The temperature and current monitoring circuit may be configured to monitor the working temperature of at least one electrical path in the plurality of cables 12 and/or the working current of the at least one electrical path. When the working temperature of the at least one electrical path is greater than a preset temperature value, or when the working current of the at least one electrical path is greater than a preset current value, the microcontroller confirms that the working status of the plurality of cables 12 is abnormal, and opens a specific electrical path (for example, a pin S0 or a pin S1) in the plurality of cables 12 between the first connector 14 and the second connector 16, so that the electronic device 20 stops working. The preset temperature value or the preset current value may be determined by obtaining, through experiments, a temperature value or a current value at which the plurality of cables 12 may be burned due to a high temperature. In another embodiment, when the working temperature of at least one electrical path is greater than a preset temperature value, or when a working current of at least one electrical path is greater than a preset current value, the microcontroller confirms that the working status of the plurality of cables 12 is abnormal, and the microcontroller may cause the buzzer operate to generate a sound to remind a user that the working status of the plurality of cables 12 is abnormal.

In some embodiments, the printed circuit board 181 in the monitoring device 18 may be provided with a temperature and voltage monitoring circuit. The temperature and voltage monitoring circuit may be for example composed of circuit elements such as a plurality of thermistors, a plurality of resistors, and a microcontroller. The temperature and voltage monitoring circuit may be configured to monitor the working temperature of at least one electrical path in the plurality of cables 12 and/or the working voltage of the at least one electrical path. When the working temperature of the at least one electrical path is greater than a preset temperature value, or when the working voltage of the at least one electrical path is less than a preset voltage value, the microcontroller confirms that the working status of the plurality of cables 12 is abnormal, and opens a specific electrical path (for example, a pin S0 or a pin S1) in the plurality of cables 12 between the first connector 14 and the second connector 16, so that the electronic device 20 stops working. The preset temperature value or the preset voltage value may be determined by obtaining, through experiments, a temperature value or a voltage value at which the plurality of cables 12 may be burned due to a high temperature. In another embodiment, when the working temperature of at least one electrical path is greater than a preset temperature value, or when a working voltage of at least one electrical path is less than a preset voltage value, the microcontroller confirms that the working status of the plurality of cables 12 is abnormal, and the microcontroller may cause the buzzer operate to generate a sound to remind a user that the working status of the plurality of cables 12 is abnormal.

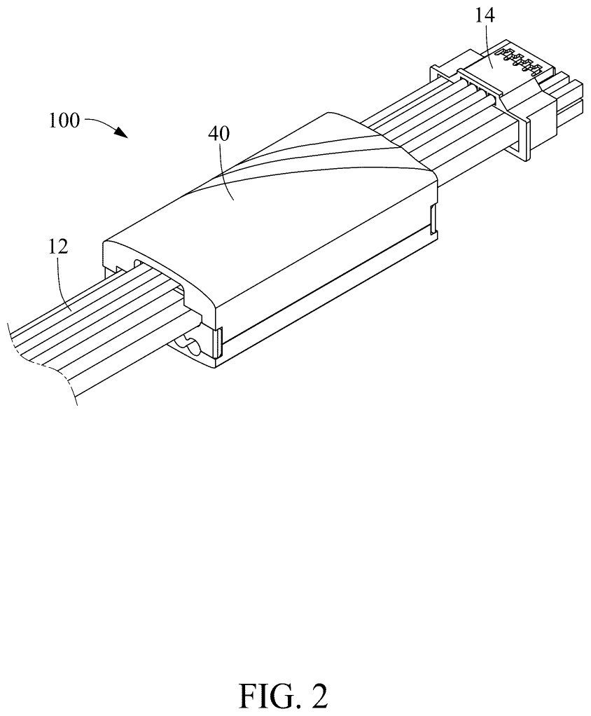

FIG. 2 is a partial schematic diagram showing an appearance of a monitoring device 18 arranged in a cable organizer 40 according to an embodiment of the present disclosure.

Referring to FIG. 2, the cable organizer 40 may be fixed on a plurality of cables 12. The cable organizer 40 is configured to concentrate and arrange the plurality of cables 12. The cable organizer 40 may be made of a material such as plastic, rubber, or silica gel. A position of the cable organizer 40 may be arranged in a middle position of the plurality of cables 12, in a position close to the first connector 14 on the plurality of cables 12, in a position close to the first connector 14 on the plurality of cables 12, in a position adjacent to the first connector 14 on the plurality of cables 12, or in a position adjacent to the second connector 16 on the plurality of cables 12. In another embodiment, a printed circuit board 181 in the monitoring device 18 may not be arranged in the cable organizer 40, and the printed circuit board 181 may be covered with a heat shrink tube, to protect the printed circuit board 181.

FIG. 3 is a schematic diagram showing an exploded structure of a cable organizer 40 according to an embodiment of the present disclosure.

Referring to FIG. 3, the cable organizer 40 includes a first clamp 41, a second clamp 42, and a base body 43. The first clamp 41 and the second clamp 42 may be engaged with each other in a snap-fit manner, but the present disclosure is not limited thereto. In some embodiments, the first clamp 41 and the second clamp 42 may be engaged with each other through bonding or screwing. The cable organizer 40 may be fixed on a plurality of cables 12. The plurality of cables 12 may include a set of cables 121, a set of cables 122, and a set of cables 123.

The first clamp 41 is configured to cover upper surfaces of the set of cables 121 of the plurality of cables 12. The first clamp 41 has a plurality of recesses (not shown in the figure) to accommodate the set of cables 121. In this embodiment, a quantity of the set of cables 121 is 6, and a quantity of recesses is 6.

The second clamp 42 is configured to be engaged with the first clamp 41, so that the cable organizer 40 is fixed on the plurality of cables 12.

The base body 43 is arranged between the first clamp 41 and the second clamp 42. The base body 43, the first clamp 41, and the second clamp 42 form the cable organizer 40. A plurality of recesses (not shown in the figure) are provided on two different ends of a top side of the base body 43, and a plurality of recesses (not shown in the figure) are provided on two different ends of a bottom side of the base body 43. The recesses on the top side of the base body 43 may accommodate the set of cables 121, and the recesses on the bottom side of the base body 43 may accommodate the set of cables 122. The base body 43 is configured to accommodate and arrange the plurality of cables 12. More specifically, the base body 43 is configured to accommodate and arrange the set of cables 121 and the set of cables 122 respectively.

A printed circuit board 181 of a monitoring device 18 is arranged between the second clamp 42 and the base body 43. One of the set of cables 123 exposes a core wire 123b, and the core wire 123b may be electrically connected to a connection pad of the printed circuit board 181. The foregoing cable with the core wire 123b exposed may be a cable with a pin of a 12VHPWR connector being defined as S0. In another embodiment, the foregoing cable with the core wire 123b exposed may be a cable with the pin of the 12VHPWR connector being defined as S1. In this way, a determination as to determine, based on a working status of the plurality of cables 12, whether to open a specific electrical path in the plurality of cables 12 between the first connector 14 and the second connector 16 can be implemented through the monitoring device 18, so that an electronic device 20 stops working.

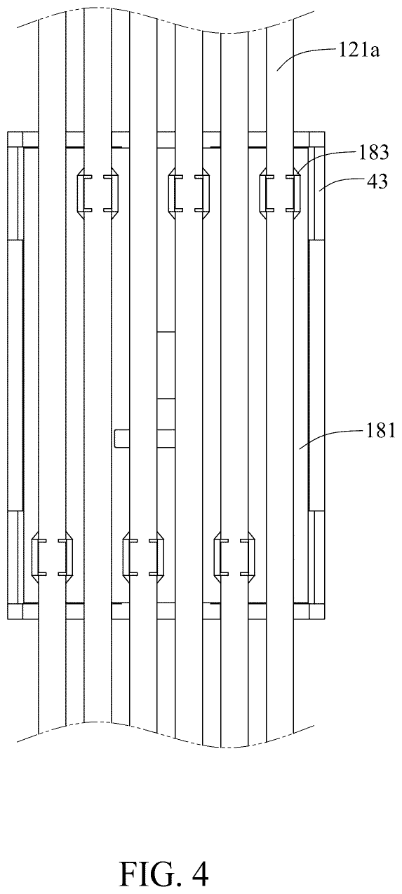

FIG. 4 is a partial schematic structural diagram showing a plurality of cables 12 arranged on a printed circuit board 181 according to an embodiment of the present disclosure.

A base body 43 may accommodate and arrange the plurality of cables 12. The printed circuit board 181 is provided with a plurality of piercing terminals 183. The piercing terminals 183 may be configured to pierce insulating outer sheaths 121a of the plurality of cables 12 and electrically connect to core wires 121b in the plurality of cables 12, to obtain a working status of the plurality of cables 12. In addition, the piercing terminal 183 may further be electrically connected to the core wires 121b in the plurality of cables 12 to obtain power required for operation of a monitoring device 18.

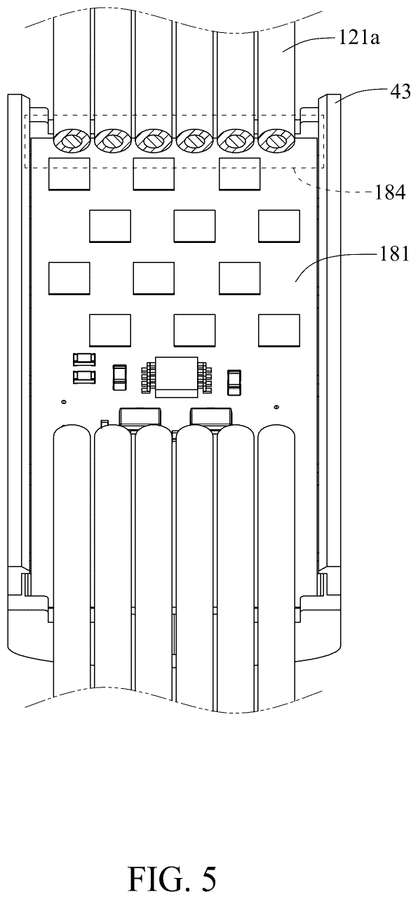

FIG. 5 is a partial schematic structural diagram showing a plurality of cables 12 arranged on a printed circuit board 181 according to another embodiment of the present disclosure.

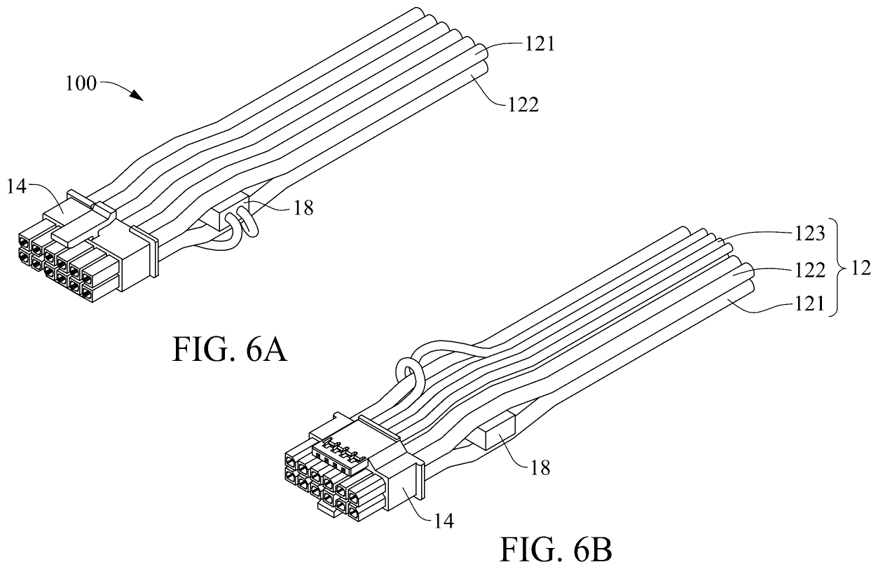

A difference between the embodiment of FIG. 5 and the embodiment of FIG. 4 is that the plurality of cables 12 of FIG. 6 are electrically connected to the printed circuit board 181 through segmented welding. A temperature sensing element (for example, a thermistor) may be arranged in a region 184 to monitor a working temperature of the plurality of cables 12.

FIG. 6A is a partial schematic diagram showing an appearance of a monitoring device 18 arranged in a plurality of cables 12 according to still another embodiment of the present disclosure.

Referring to FIG. 6A, the monitoring device 18 is arranged in the plurality of cables 12. More specifically, the monitoring device 18 is arranged between a set of cables 121 and a set of cables 122 in the plurality of cables 12, and is adjacent to a first connector 14. The set of cables 121 and the set of cables 122 may cover upper and lower surfaces of the monitoring device 18. In this embodiment, the monitoring device 18 may be composed of a temperature control switch. When a working temperature of the plurality of cables 12 exceeds a critical temperature value of the temperature control switch, the temperature control switch operates to open a specific electrical path in a set of cables 123 (as shown in FIG. 6B).

It should be particularly noted that the modular cable 100 in FIG. 6A may omit manufacturing costs of the printed circuit board 181, thereby achieving the function of protecting an electronic device at lower costs. In another embodiment, the monitoring device 18 may also be arranged between the set of cables 121 and the set of cables 122, and is adjacent to a second connector 16. In another embodiment, the monitoring device 18 may also be arranged between the set of cables 121 and the set of cables 122, and is located in the middle of the first connector 14 and the second connector 16.

FIG. 6B is a partial schematic diagram showing an appearance of a monitoring device 18 arranged in a plurality of cables 12 after being flipped 180 degrees according to FIG. 6A.

Referring to FIG. 6B, it may be more clearly seen that the plurality of cables 12 include a set of cables 121, a set of cables 122, and a set of cables 123. A specific cable in the set of cables 123 is connected in series with the monitoring device 18. The foregoing specific cable may be a cable with a pin of a 12VHPWR connector being defined as S0. In another embodiment, the foregoing specific cable may be a cable with a pin of the 12VHPWR connector being defined as S1.

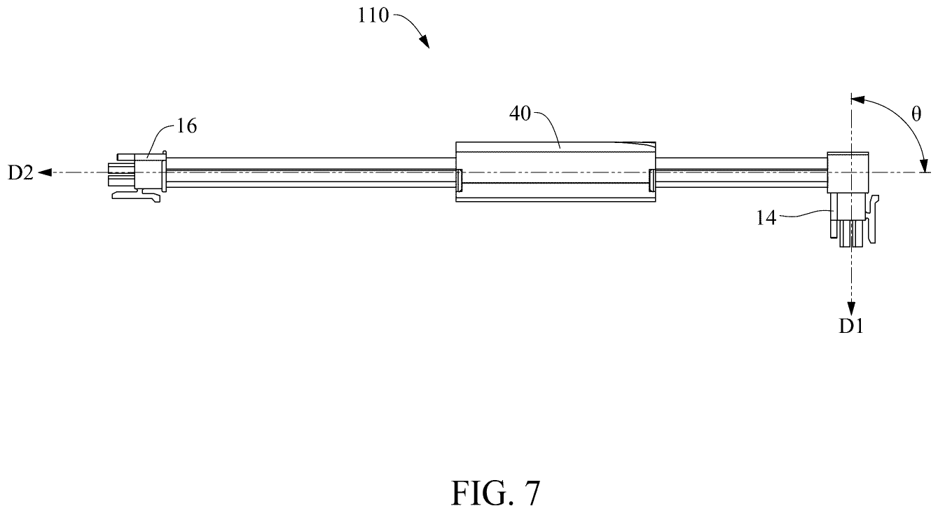

FIG. 7 is a schematic structural diagram showing an appearance according to still another embodiment of the present disclosure. A cable organizer 40 is arranged between a first connector 14 and a second connector 16 in a modular cable 110. The first connector 14 in the modular cable 110 has a first arrangement direction D1. The second connector 16 in the modular cable 110 has a second arrangement direction D2. A specific included angle between the second arrangement direction D2 and the first arrangement direction D1 is θ. The specific angle θ may be between 80 degrees and 110 degrees, and may be preferably 90 degrees. In addition, a steering structure design of the first connector 14 may alleviate a problem of current concentration on some lines as a result of the cables 110 between an electronic device 20 and the first connector 14 being excessively bent. In another embodiment, the cable organizer 40 may be close to the first connector 14. In another embodiment, the cable organizer 40 may be close to the second connector 16.

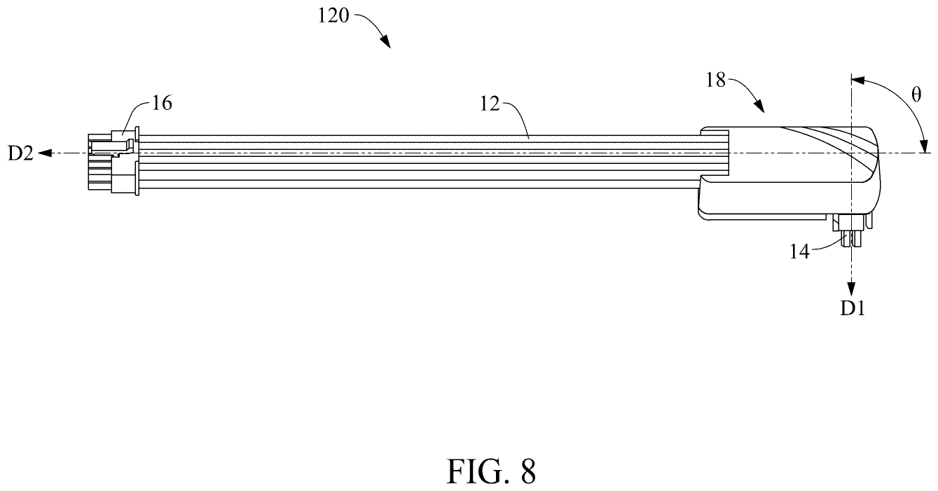

FIG. 8 is a schematic structural diagram showing an appearance according to yet another embodiment of the present disclosure. A monitoring device 18 is located close to a first connector 14 in a modular cable 120. The first connector 14 in the modular cable 120 has a first arrangement direction D1. A second connector 16 in the modular cable 120 has a second arrangement direction D2. A specific included angle between the second arrangement direction D2 and the first arrangement direction D1 is θ. The specific angle θ may be between 80 degrees and 110 degrees, and may be preferably 90 degrees. In addition, a steering structure design of the first connector 14 may alleviate a problem of current concentration on some lines as a result of the cables 120 between an electronic device 20 and the first connector 14 being excessively bent.

Based on the above, through the modular cable of the present disclosure, it may be determined, by monitoring the working status (for example, a working temperature, a working current, and/or a working voltage) of the plurality of cables, whether the cable may be abnormal, and when it is confirmed that the working status is abnormal, and a specific electrical path in the plurality of cables between the first connector and the second connector is opened, so that the electronic device stops working, thereby achieving the function of instantly protecting the electronic device. In addition, although the electronic device stops working due to the protection function, the power supply unit for supplying power to the electronic device can still operate normally. Therefore, the computer system is not shut down just because the electronic device stops working, and some operating functions of the computer system may still be maintained, thereby improving use reliability of the computer system.

The present invention is described by way of the preferred embodiments above. A person skilled in the art should understand that, these embodiments are merely for describing the present invention and are not to be construed as limitations to the scope of the present invention. It should be noted that all equivalent changes, replacements and substitutions made to the embodiments are to be encompassed within the scope of the present invention. Therefore, the scope of protection of the present invention should be accorded with the broadest interpretation of the appended claims.

What is claimed is:

1. A modular cable, connected to an electronic device and a power supply unit, having a function of protecting the electronic device, and comprising:
a plurality of cables;
a first connector, electrically connected to one ends of the plurality of cables, the first connector being configured to detachably connect to the electronic device;
a second connector, electrically connected to other ends of the plurality of cables, the second connector being configured to detachably connect to the power supply unit; and
a monitoring device, arranged on the plurality of cables and located between the first connector and the second connector, the monitoring device being configured to monitor a working status of all electrical paths of the plurality of cables, and when the working status is abnormal, open a specific electrical path in the plurality of cables between the first connector and the second connector, so that the electronic device stops working.

2. The modular cable according to claim 1, wherein the first connector and the second connector are 12VHPWR connectors, and the specific electrical path refers to a path electrically connected to a pin of the 12VHPWR connector that is defined as S0.

3. The modular cable according to claim 1, wherein the first connector and the second connector are 12VHPWR connectors, and the specific electrical path refers to a path electrically connected to a pin of the 12VHPWR connector that is defined as S1.

4. The modular cable according to claim 1, wherein the monitoring device is further provided with a temperature monitoring circuit, which is configured to monitor a working temperature of at least one electrical path in the plurality of cables, and when the working temperature of the at least one electrical path is greater than a preset temperature value, confirm that the working status is abnormal, and open the specific electrical path.

5. The modular cable according to claim 1, wherein the monitoring device is further provided with a current monitoring circuit, which is configured to monitor a working current of at least one electrical path in the plurality of cables, and when the working current of the at least one electrical path is greater than a preset current value, confirm that the working status is abnormal, and open the specific electrical path.

6. The modular cable according to claim 1, wherein the monitoring device is further provided with a voltage monitoring circuit, which is configured to monitor a working voltage of at least one electrical path in the plurality of cables, and when the working voltage of the at least one electrical path is less than a preset voltage value, confirm that the working status is abnormal, and open the specific electrical path.

7. The modular cable according to claim 1, wherein the monitoring device is arranged in a cable organizer, the cable organizer comprising:
a first clamp, configured to cover upper surfaces of a set of cables of the plurality of cables;
a second clamp, configured to be engaged with the first clamp, so that the cable organizer is fixed on the plurality of cables; and
a base body, arranged between the first clamp and the second clamp, and configured to accommodate and arrange the plurality of cables.

8. The modular cable according to claim 7, wherein the monitoring device further comprises a printed circuit board arranged between the second clamp and the base body.

9. The modular cable according to claim 8, wherein the printed circuit board is further provided with a plurality of piercing terminals, which are configured to pierce insulating outer sheaths of the plurality of cables and electrically connect to core wires in the plurality of cables, to obtain the working status of the plurality of cables.

10. The modular cable according to claim 1, wherein the monitoring device is a temperature control switch, which is configured to monitor a working temperature of at least one electrical path in the plurality of cables, and when the working temperature of the at least one electrical path is greater than a preset temperature value, confirm that the working status is abnormal, and open the specific electrical path.

11. The modular cable according to claim 1, wherein the monitoring device is close to the first connector, the first connector has a first arrangement direction, the second connector has a second arrangement direction, and an included angle between the first arrangement direction and the second arrangement direction is 90 degrees.
